(19) United States
(12) Patent Application Publication
(10) Pub. No.: US 2021/0283882 A1
(43) Pub. Date: Sep. 16, 2021

(54) POLYIMIDE FILM FOR METAL LAMINATION AND POLYIMIDE METAL LAMINATE USING SAME

(71) Applicant: Ube Industries, Ltd., Yamaguchi (JP)

(72) Inventor: Shin-ichiro KOHAMA, Yamaguchi (JP)

(21) Appl. No.: 16/341,578

(22) PCT Filed: Oct. 27, 2017
(86) PCT No.: PCT/JP2017/038889

§ 371 Date: Apr. 12, 2019

(30) Foreign Application Priority Data
Oct. 31, 2016 (JP) 2016-212681
Mar. 21, 2017 (JP) 2017-054041

(51) Int. Cl. B32B 15/08; C08G 73/10; B32B 27/28; C08J 5/18; B32B 27/18; C09J 7/25

(52) U.S. Cl. CPC B32B 15/08; C08G 73/1071; B32B 27/281; B32B 2307/306; B32B 27/18; C09J 7/25; C08J 5/18

(57) ABSTRACT

The present invention discloses a polyimide film for metal lamination, which is obtained by providing at least one surface of a heat-resistant polyimide layer with a metal bonding layer. This polyimide film has a 5% weight loss temperature of 500° C. or higher in a nitrogen atmosphere, while having a dielectric loss tangent of 0.007 or less at a frequency of 11.4 GHz. It is preferable that the metal bonding layer is formed of a thermally fusible polyimide, or is formed of a heat-resistant polyimide and a silane coupling agent. The present invention also discloses a polyimide metal laminate which is obtained by additionally laminating a metal layer on a surface of the above-described polyimide film for metal lamination, said surface having been provided with the metal bonding layer.

### TECHNICAL FIELD

The present invention relates to a polyimide film for metal lamination and a polyimide metal laminate using the polyimide film for metal lamination.

### BACKGROUND ART

Polyimide films are widely used as a circuit board material for flexible printed circuits (FPCs) used for wiring and the like of various electronic devices. As a polyimide film used for FPCs, Patent Literature 1 discloses a polyimide film having thermal fusion-bondable properties in which a thermal fusion-bondable polyimide layer is laminated on a heat-resistant polyimide layer. Patent Literature 1 also discloses a copper clad laminate using the polyimide film.

With recent improvements to the performance of electronic devices, there is a demand for higher frequencies of transmission signals. However, since conventional polyimide films have high dielectric constants and dielectric loss tangents, there is the problem of high transmission losses in a high-frequency range. To address this issue, Patent Literatures 2 and 3 propose polyimide films in which the dielectric constant and the dielectric loss tangent are reduced by introducing a long-chain skeleton into the molecular chain of polyimide and thereby lowering the concentration of imide groups in molecules.

### CITATION LIST

### Patent Literature

Patent Literature 1: WO 2013/157565

Patent Literature 2: JP 2015-199328A

Patent Literature 3: JP 2015-209461A

### SUMMARY OF INVENTION

However, the methods for reducing the dielectric constant and the dielectric loss tangent by lowering the concentration of imide groups may compromise the original heat-resistance and mechanical properties of polyimide. Therefore, it is an object of the present invention to provide a polyimide film for metal lamination in which the dielectric constant and the dielectric loss tangent are reduced without compromising high heat resistance and mechanical properties.

Aspects of the present invention relate to the following items.

1. A polyimide film for metal lamination including a heat-resistant polyimide layer and a metal adhesion layer which is provided on at least one side of the heat-resistant polyimide layer,

a 5% weight loss temperature in a nitrogen atmosphere being 500° C. or greater, and

a dielectric loss tangent at a frequency of 11.4 GHz being 0.007 or less.

2. The polyimide film for metal lamination as set forth in item 1 above, wherein a polyimide that composes the heat-resistant polyimide layer is a polyimide including a repeating unit represented by a chemical formula (1) below:

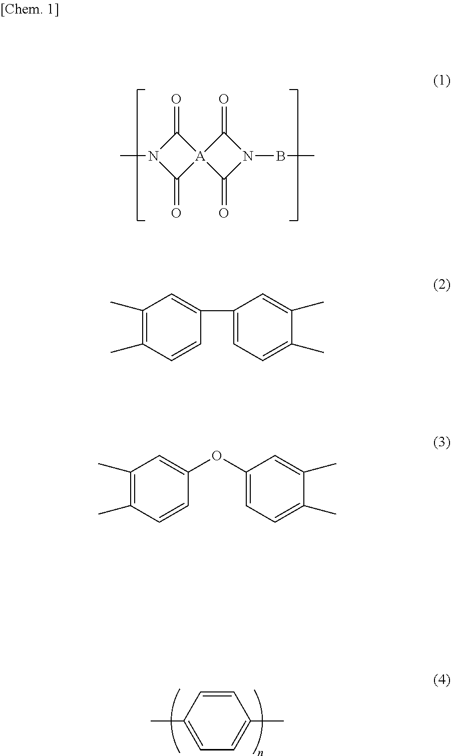

wherein, in the formula (1),

A represents a group represented by a chemical formula (2) below in an amount of 50 to 100 mol % and a group represented by a chemical formula (3) below in an amount of 0 to 50 mol %, and

B represents a group represented by a chemical formula (4) below in an amount of 50 to 100 mol % and may optionally include two or more types of groups, and, in the formula (4), “n” represents an integer of 1 to 4.

3. The polyimide film for metal lamination as set forth in item 1 or 2 above, wherein the metal adhesion layer includes a thermal fusion-bondable polyimide.
4. The polyimide film for metal lamination as set forth in item 1 or 2 above, wherein the metal adhesion layer includes a heat-resistant polyimide and a silane coupling agent.
5. A polyimide metal laminate including: the polyimide film for metal lamination as set forth in any one of items 1 to 4 above; and a metal layer laminated on the side of the polyimide film on which the metal adhesion layer is arranged.

### DESCRIPTION OF EMBODIMENTS

### Polyimide Film for Metal Lamination

A polyimide film for metal lamination of the present invention includes a heat-resistant polyimide layer (core layer) and a metal adhesion layer which is provided on at least one side of the heat-resistant polyimide layer. The metal adhesion layer is a layer that is used to make a metal layer adhere to the polyimide film for metal lamination of the present invention. An embodiment of the polyimide film for metal lamination of the present invention is, for example, a multilayer thermal fusion-bondable polyimide film. The multilayer thermal fusion-bondable polyimide film includes; a heat-resistant polyimide layer; and a thermal fusion-bondable polyimide layer (thermal fusion-bondable layer) which is used as the metal adhesion layer and which is laminated on at least one side of the heat-resistant polyimide layer. Another embodiment of the polyimide film for metal lamination of the present invention is, for example, a surface-modified polyimide film. The surface-modified polyimide film includes: a heat-resistant polyimide layer; and, as the metal adhesion layer, a polyimide layer (surface modification layer) which is formed on at least one side of the heat-resistant polyimide layer, the polyimide layer including a heat-resistant polyimide and a silane coupling agent and having improved adhesion properties.

As used herein, “heat-resistant” means that the glass transition temperature (Tg) is 350° C. or greater, or Tg is not observed below the decomposition temperature. Moreover, as used herein, “thermal fusion-bondable” means that the softening point is less than 350° C. The softening point is the temperature at which a substance abruptly softens during heating, and in the case of an amorphous polyimide, Tg is the same as the softening point, whereas in the case of a crystalline polyimide, the melting point is the same as the softening point. Note that it is preferable that the polyimide film for metal lamination of the present invention has a softening point of 200° C. or greater.

### Heat-Resistant Polyimide Layer (Core Layer)

The heat-resistant polyimide layer is composed of a heat-resistant polyimide obtained by polymerizing a tetracarboxylic acid component and a diamine component.

In the above-described heat-resistant polyimide, it is preferable that 3,3′,4,4′-biphenyltetracarboxylic dianhydride is used as a tetracarboxylic acid component in an amount of 50 to 100 mol % in all the tetracarboxylic acid components. Furthermore, at least one tetracarboxylic dianhydride selected from pyromellitic dianhydride and 4,4′-oxydiphthalic dianhydride may also be used in an amount of less than 50 mol % in all the tetracarboxylic acid components. The total amount of these tetracarboxylic acid components is preferably 70 mol % or greater, more preferably 80 mol % or greater, and even more preferably 90 mol % or greater in all the tetracarboxylic acid components. Moreover, other tetracarboxylic acid components other than the above-described tetracarboxylic acid components may also be used in an amount of less than 50 mol % in all the tetracarboxylic acid components.

In the above-described heat-resistant polyimide, it is preferable that at least one diamine selected from p-phenylenediamine, benzidine, 4,4″-diamino-p-terphenyl, and 4,4′″-diamino-p-quaterphenyl, which serve as diamine components, is used in an amount of 50 to 100 mol % in all the diamine components. The total amount of these diamine components is preferably 70 mol % or greater, more preferably 80 mol % or greater, and even more preferably 90 mol % or greater in all the diamine components. Moreover, other diamines such as, for example, 4,4′-diaminodiphenylether, may also be used in an amount of less than 50 mol % in all the diamines.

An example of a polyimide that is suitable for use in the heat-resistant polyimide layer of the present invention is a polyimide constituted by a repeating unit represented by a chemical formula (1) below.

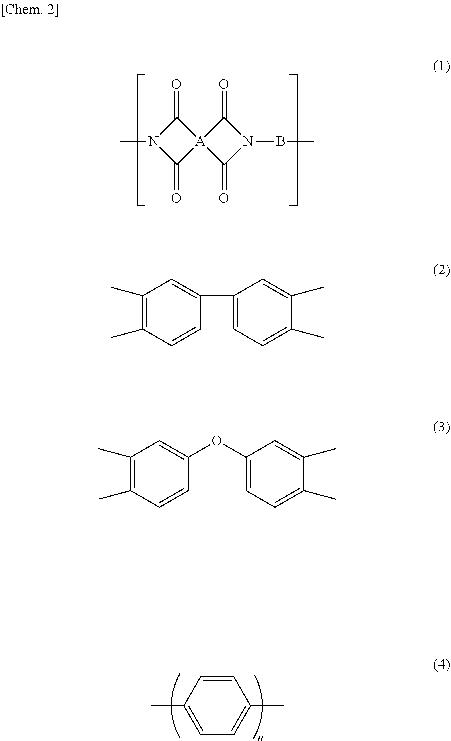

In the formula (1), A represents a group represented by a chemical formula (2) below in an amount of 50 to 100 mol % and a group represented by a chemical formula (3) below in an amount of 0 to 50 mol %; and B represents a group represented by a chemical formula (4) below in an amount of 50 to 100 mol % and may optionally include two or more types of groups. In the formula (4), “n” represents an integer of 1 to 4.

### Thermal Fusion-Bondable Polyimide Layer (Thermal Fusion-Bondable Layer)

The thermal fusion-bondable polyimide layer is composed of a thermal fusion-bondable polyimide obtained by polymerizing a tetracarboxylic acid component and a diamine component.

In the thermal fusion-bondable polyimide, it is preferable that at least one tetracarboxylic dianhydride selected from 3,3′,4,4′-biphenyltetracarboxylic dianhydride, 2,3,3′,4′-biphenyltetracarboxylic dianhydride, and pyromellitic dianhydride, which serve as tetracarboxylic acid components, is used in an amount of 50 to 100 mol % in all the tetracarboxylic acid components. The total amount of these tetracarboxylic acid components is preferably 70 mol % or greater, more preferably 80 mol % or greater, and even more preferably 90 mol % or greater in all the tetracarboxylic acid components.

In the above-described thermal fusion-bondable polyimide, it is preferable that a diamine represented by a chemical formula (5) below, which serves as a diamine component, is used in an amount of 50 to 100 mol % in all the diamine components. The total amount of these diamine components is preferably 70 mol % or greater, more preferably 80 mol % or greater, and even more preferably 90 mol % or greater in all the diamine components.

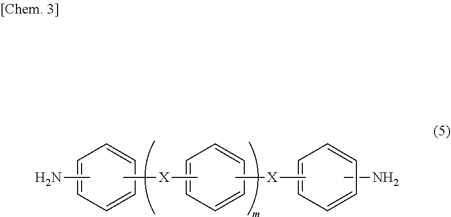

In the formula (5), X represents O, CO, C(CH₃)₂, CH₂, SO₂, S, or a direct bond and may optionally have two or more different types of bonds, and “m” represents an integer of 0 to 4.

Examples of the diamine represented by the chemical formula (5) above include 1,3-bis(4-aminophenoxy)benzene, 1,4-bis(4-aminophenoxy)benzene, 4,4′-bis(3-aminophenoxy)biphenyl, 4,4′-bis(4-aminophenoxy)biphenyl, 3,3′-diaminobenzophenone, bis[4-(3-aminophenoxy)phenyl]ketone, bis[4-(4-aminophenoxy)phenyl]ketone, bis[4-(3-aminophenoxy)phenyl]sulfide, bis[4-(4-aminophenoxy)phenyl]sulfide, bis[4-(3-aminophenoxy)phenyl]sulfone, bis[4-(4-aminophenoxy)phenyl]sulfone, bis[4-(3-aminophenoxy)phenyl]ether, bis[4-(4-aminophenoxy)phenyl]ether, 2,2-bis[4-(4-aminophenoxy)phenyl]propane, 2,2-bis[4-(3-aminophenoxy)phenyl]propane, and the like. It is possible to use two or more diamines in combination as diamine components.

A coupling agent may also be mixed in the thermal fusion-bondable polyimide layer as necessary, and examples of the coupling agent include a silane coupling agent and a titanate coupling agent. It is possible to use a silane coupling agent and a titanate coupling agent that are similar to those used in the surface modification layer, which will be described layer.

A fine inorganic or organic filler can be mixed in the above-described heat-resistant polyimide layer and the above-described thermal fusion-bondable polyimide layer as necessary. The inorganic filler may be particle-shaped or flat-shaped. Examples of the inorganic filler include minute particle-shaped inorganic oxide powders, such as a titanium dioxide powder, a silicon dioxide (silica) powder, a magnesium oxide powder, an aluminum oxide (alumina) powder, and a zinc oxide powder; minute particle-shaped inorganic nitride powders, such as a silicon nitride powder and a titanium nitride powder; minute particle-shaped inorganic carbide powders, such as a silicon carbide powder; and minute particle-shaped inorganic salt powders, such as a calcium carbonate powder, a calcium sulfate powder, and a barium sulfate powder. Examples of the organic filler include polyimide particles, particles of a thermosetting resin, and the like. These fillers may be used in a combination of two or more. It is preferable that the amount and shape (size and aspect ratio) of fillers that are used are chosen depending on the use. Moreover, in order to uniformly disperse these fillers, a known means can be applied.

### Surface Modification Layer

The surface modification layer is a polyimide layer composed of a heat-resistant polyimide and a silane coupling agent and having improved adhesion properties. The heat-resistant polyimide that is used may be the same as or different from the polyimide that forms the heat-resistant polyimide layer (core layer). The surface modification layer can be formed using a method described later.

Examples of the silane coupling agent include epoxy silanes such as γ-glycidoxypropyltrimethoxysilane, γ-glycidoxypropyldiethoxysilane, and β-(3,4-epoxycyclohexyl)ethyltrimethoxysilane; vinyl silanes such as vinyltrichlorosilane, vinyltris(β-methoxyethoxy)silane, vinyltriethoxysilane, and vinyltrimethoxysilane; acryl silanes such as γ-methacryloxypropyltrimethoxysilane; aminosilanes such as N-β-(aminoethyl)-γ-aminopropyltrimethoxysilane, N-β-(aminoethyl)-γ-aminopropylmethyldimethoxysilane, γ-aminopropyltriethoxysilane, and N-phenyl-y-aminopropyltrimethoxysilane; as well as y-mercaptopropyltrimethoxysilane and y-chloropropyltrimethoxysilane.

Among these, aminosilane coupling agents, such as γ-aminopropyltriethoxysilane, N-β-(aminoethyl)-γ-aminopropyl-triethoxysilane, N-(aminocarbonyl)-γ-aminopropyltriethoxysilane, N-[β-(phenylamino)-ethyl]-γ-aminopropyltriethoxysilane, N-phenyl-γ-aminopropyltriethoxysilane, and N-phenyl-γ-aminopropyltrimethoxysilane, are preferable, and, in particular, N-phenyl-γ-aminopropyltrimethoxysilane is preferred.

Moreover, a titanate coupling agent may be used instead of the above-described silane coupling agent. For example, as the titanate coupling agent, it is possible to use isopropyl triisostearoyl titanate, isopropyl tridecyl benzenesulfonyl titanate, isopropyl tris(dioctyl pyrophosphate)titanate, tetraisopropyl bis(dioctyl phosphite)titanate, tetra(2,2-diallyl oxymethyl-1-butyl)bis(di-tridecyl)phosphite titanate, bis(dioctyl pyrophosphate)oxyacetate titanate, bis(dioctyl pyrophosphate)ethylene titanate, isopropyltrioctanoil titanate, isopropyltricumyiphenyl titanate, and the like.

It is preferable that the polyimide film for metal lamination of the present invention has sufficient heat resistance. For example, the 5% weight loss temperature of the polyimide film in a nitrogen atmosphere is preferably 500° C. or greater, more preferably 530° C. or greater, even more preferably 550° C. or greater, and yet more preferably 560° C. or greater.

Moreover, it is preferable that the polyimide film for metal lamination of the present invention has favorable signal transmission properties in a high-frequency range, and, for example, the dielectric loss tangent of the polyimide film at a frequency of 11.4 GHz is preferably 0.007 or less, more preferably 0.006 or less, and even more preferably 0.005 or less.

It is not preferable that water is contained in the polyimide film for metal lamination of the present invention due to the polyimide film absorbing moisture, because this leads to an increase in the dielectric constant and the dielectric loss tangent. For this reason, the polyimide film for metal lamination of the present invention has a saturated moisture absorption of preferably 1.3 mass % or less, more preferably 1.1 mass % or less, and even more preferably 0.9 mass % or less. Moreover, the polyimide film for metal lamination of the present invention has a moisture absorption of preferably 0.7 mass % or less, more preferably 0.5 mass % or less, and even more preferably 0.4 mass % or less at a temperature of 25° C. and a relative humidity (RH) of 60%.

### Method for Producing Thermal Fusion-Bondable Polyimide Film

A thermal fusion-bondable polyimide film, which is an embodiment of the present invention, can be produced by applying a polyimide precursor solution (polyamic acid solution) that forms a thermal fusion-bondable polyimide to one or both sides of a self-supporting film obtained from a polyimide precursor solution (polyamic acid solution) that forms a heat-resistant polyimide, and heating and drying the resultant multilayer self-supporting film to thereby perform imidization.

It is preferable that the above-described coupling agent or filler is added to the polyimide precursor solutions, and furthermore, a basic organic compound may also be added to the polyimide precursor solutions for the purpose of accelerating the imidization. For example, imidazole, 2-methylimidazole, 1,2-dimethylimidazole, 2-phenylimidazole, benzimidazole, isoquinoline, substituted pyridine, or the like can be used in a ratio of 0.05 to 10 mass %, preferably 0.05 to 5 mass %, and particularly preferably 0.1 to 2 mass % with respect to a polyamic acid (polyimide precursor). The use of these compounds allows a polyimide film to be formed at a relatively low temperature, and therefore, these compounds are used to avoid insufficient imidization.

Examples of an organic solvent for producing the above-described polyimide precursor solutions include amides, such as N-methyl-2-pyrrolidone, N,N-dimethylacetamide, N,N-diethylacetamide, N,N-dimethylformamide, N,N-diethylformamide, and hexamethylsulfolamide; sulfoxides, such as dimethyl sulfoxide and diethyl sulfoxide; and sulfones, such as dimethyl sulfone and diethyl sulfone. These solvents may be used alone or may be used as a mixture.

For example, the polyimide precursor solution can be produced as a polyamic acid solution by mixing a tetracarboxylic acid component and a diamine component in substantially equimolar amounts, or in such amounts that the amount of either component (the acid component or the diamine component) is slightly larger than that of the other, and causing these components to react with each other at a reaction temperature of 100° C. or less, preferably 80° C. or less, and more preferably 0 to 60° C. for about 0.2 to 60 hours.

Moreover, it is also possible to produce the thermal fusion-bondable polyimide film of the present invention using a coextrusion-casting film forming method (also referred to simply as “coextrusion method”). Specifically an extruder having two or more layers of extrusion dies is used. A polyimide precursor solution that forms a heat-resistant polyimide layer and a polyimide precursor solution that forms a thermal fusion-bondable polyimide layer are cast on a support from discharge ports of the dies to form a laminated thin film-like body. Then, the thin film-like body on the support is dried to form a multilayer self-supporting film, and this film is heated and dried, thereby performing imidization.

### Method for Producing Surface-Modified Polyimide Film

A surface-modified polyimide film, which is another embodiment of the present invention, can be produced by applying a silane coupling agent solution to one or both sides of a self-supporting film obtained from a polyimide precursor solution (polyamic acid solution) that forms a heat-resistant polyimide, and performing imidization through heating and drying. In this case, the heat-resistant polyimide that constitutes the core layer and the heat-resistant polyimide that constitutes the surface modification layer are the same.

Moreover, it is also possible to produce the surface-modified polyimide film by applying a polyimide precursor solution that contains a polyimide precursor and a silane coupling agent and forms a heat-resistant polyimide that is different from the heat-resistant polyimide constituting the core layer to one or both sides of the above-described self-supporting film, and performing imidization through heating and drying. In this case, the heat-resistant polyimide constituting the core layer and the heat-resistant polyimide constituting the surface modification layer are different from each other.

A polyimide precursor solution similar to that used in the production of the above-described thermal fusion-bondable polyimide film can be used as the polyimide precursor solution that forms the heat-resistant polyimide. Moreover, the solvent of the solution that is applied is preferably a solvent that is compatible with the solvent contained in the self-supporting film, and is more preferably the same solvent as that contained in the self-supporting film.

### Polyimide Metal Laminate

An embodiment of the polyimide metal laminate of the present invention includes: the above-described thermal fusion-bondable polyimide film; a sheet of metal foil, such as copper foil, which is laminated on a side of the thermal fusion-bondable polyimide film on which the thermal fusion-bondable polyimide are arranged. The sheet of metal foil may be laminated on both sides of the thermal fusion-bondable polyimide film or only on one side of the thermal fusion-bondable polyimide film.

Examples of the metal foil include aluminum foil, copper foil, and stainless steel foil. For FPCs, copper foil is usually used. Specific examples of the copper foil include rolled copper foil, electro-deposited copper foil, and the like. The thickness of the copper foil is not limited to a specific thickness, but is preferably 2 to 35 μm and particularly preferably 5 to 18 μm. In the case of copper foil having a thickness of 5 μm or less, copper foil with a carrier, for example, copper foil with an aluminum foil carrier can be used.

The above-described polyimide metal laminate can be produced by laying a sheet of metal foil on the side of the above-described thermal fusion-bondable polyimide film on which the thermal fusion-bondable polyimide layer has been laminated and thermocompression-bonding the sheet of metal foil thereto. It is preferable that the thermal fusion-bondable polyimide film and the sheet of metal foil are continuously thermocompression-bonded using at least a pair of pressure-applying members under heating conditions in which the temperature of a pressure-applying portion is 30° C. or more higher than the glass transition temperature of the thermal fusion-bondable polyimide and is 420° C. or less. Specifically, it is preferable that the thermocompression bonding is performed within a temperature range from 350° C. to 420° C.

A pair of pressure-bonding metal rolls (pressure-bonding portions thereof may be made of a metal or a ceramic-sprayed metal), a double belt press, and a hot press can be used as the pressure-applying members. In particular, pressure-applying members with which thermocompression bonding and cooling can be performed under pressure, and among these, a hydraulic double belt press can be particularly preferably used. Moreover, a polyimide metal laminate can also be obtained in a simple manner through roll laminating using a pair of pressure-bonding metal rolls.

Another embodiment of the polyimide metal laminate of the present invention is a polyimide metal laminate in which a first metal layer is laminated through metallization on the side of the above-described surface-modified polyimide film on which the surface modification layer has been provided, and a second metal layer is further laminated on the surface of the first metal layer through plating. These metal layers may be provided on both sides or only on one side of the surface-modified polyimide film.

Metallization is a method for forming a metal layer using vacuum deposition, sputtering, ion plating, electron beam, or the like instead of metal plating or metal foil lamination. The metal that is used is not limited a specific metal, but may be a metal such as copper, nickel, chromium, manganese, aluminum, iron, molybdenum, cobalt, tungsten, vanadium, titanium, or tantalum, or an alloy thereof; or an oxide of these metals; a carbide of these metals; or the like.

The number of metal layers formed through metallization can be appropriately selected depending on the use, and may be one, two, or three or more multiple layers. With regard to the thickness of a metal layer that is formed, a thickness within a range of preferably 1 to 500 nm, or more preferably 5 nm to 200 nm is suitable for practical use.

It is possible to further form a metal layer of copper, tin, or the like on the surface of the metal layer that has been provided through metallization, using a known wet plating method such as electrolytic plating or electroless plating. The film thickness of the metal layer formed through plating is preferably within a range of 1 μm to 9 μm, because this film thickness range is suitable for practical use.

A specific example of the polyimide metal laminate is a polyimide metal laminate in which two layers, namely, a 1 nm to 30 nm Ni/Cr alloy layer and a 100 nm to 1,000 nm copper layer are laminated through metallization, and a 1 μm to 9 μm copper layer is further laminated thereon through plating.

It is preferable that the polyimide metal laminate of the present invention has a favorable adhesion strength between the metal layer and the polyimide film for metal lamination. For example, it is preferable that the peel strength as measured according to the method of JIS C6471 is preferably 0.5 N/mm or greater, or more preferably 0.7 N/mm or greater.

### EXAMPLES

Hereinafter, the present invention will be specifically described based on examples. Note that the scope of the present invention is not limited to the examples.

### Measurement Methods for Evaluations

### 1. Water Absorption of Polyimide Film

An increase in weight of a sample after having absorbed water by being immersed in water at 23° C. for 24 hours or longer, relative to the absolute dry weight of the sample was measured. Then, water absorption (saturated) was calculated using an equation below:

Water absorption (%)=[(weight after absorbing water)−(absolute dry weight)]/(absolute dry weight)×100

Similarly, water absorption (25° C., 60% RH) was calculated using a sample after having absorbed water in a constant temperature and humidity apparatus at 25° C. and 60% RH for 24 hours or longer.

### 2. Dielectric Properties of Polyimide Film

The relative dielectric constant (ε) and the dielectric loss tangent (tan δ) of a polyimide film were measured in conformity with the methods of ASTM D2520. The measurement was performed using the TM020 mode of a cylindrical resonator and at a measurement frequency of 11.4 GHz.

### 3. Coefficient of Linear Thermal Expansion of Polyimide Film

A sample with a size of 15 mm in length and 3 mm in width was subjected to measurement in a tensile mode under a load of 4 gf at a rate of increase in temperature of 20° C./min, and the coefficient of linear thermal expansion (CTE) was calculated from a TMA curve between 50° C. and 200° C.

### 4. Peel Strength of Copper Clad Laminate

The peel strength of a copper clad laminate was measured according to the method of JIS C6471.

### 5. 5% Weight Loss Temperature

Measurement was performed using an EXSTAR TG/DTA 7200 from Seiko Instruments Inc. (at a rate of increase in temperature of 10° C./min under a nitrogen or air flow).

### Abbreviations for Compounds

s-BPDA: 3,3′,4,4′-biphenyltetracarboxylic dianhydride

ODP: 4,4′-oxydiphthalic anhydride

PMDA: pyromellitic dianhydride

PPD: p-phenylenediamine

DATP: 4,4″-diamino-p-terphenyl

BAPP: 2,2-bis[4-(4-aminophenoxy)phenyl]propane

DMAc: N,N-dimethylacetamide

Synthesis of Polyamic Acid Solution A that Forms Heat-Resistant Polyimide

DMAc was added into a reaction vessel equipped with an agitator and a nitrogen inlet tube, and PPD serving as a diamine component was further added. Subsequently, s-BPDA serving as a tetracarboxylic dianhydride component was added in an approximately equimolar amount to the diamine component and caused to react therewith to obtain a polyamic acid solution A with a monomer concentration of 18 mass % and a solution viscosity of 1500 poise at 25° C.

Synthesis of Polyamic Acid Solution B that Forms Heat-Resistant Polyimide

DMAc was added into a reaction vessel equipped with an agitator and a nitrogen inlet tube, and PPD serving as a diamine component was further added. Subsequently, s-BPDA and ODPA serving as tetracarboxylic dianhydride components were added in an approximately equimolar amount to the diamine component and caused to react therewith to obtain a polyamic acid solution B with a monomer concentration of 18 mass % and a solution viscosity of 1800 poise at 25° C. The molar ratio between s-BPDA and ODPA was set to be 80:20.

Synthesis of Polyamic Acid Solution C that Forms Heat-Resistant Polyimide

A polyamic acid solution C was obtained in a manner similar to that of the synthesis of the polyamic acid solution B except that the molar ratio between s-BPDA and ODPA was set to be 70:30.

Synthesis of Polyamic Acid Solution D that Forms Heat-Resistant Polyimide

A polyamic acid solution D was obtained in a manner similar to that of the synthesis of the polyamic acid solution B except that the molar ratio between s-BPDA and ODPA was set to be 50:50.

Synthesis of Polyamic Acid Solution E that Forms Heat-Resistant Polyimide

A polyamic acid solution E was obtained in a manner similar to that of the synthesis of the polyamic acid solution B except that the molar ratio between s-BPDA and ODPA was set to be 40:60.

Synthesis of Polyamic Acid Solution F that Forms Heat-Resistant Polyimide

DMAc was added into a reaction vessel equipped with an agitator and a nitrogen inlet tube, and PPD serving as a diamine component was further added. Subsequently, s-BPDA, ODPA, and PMDA serving as tetracarboxylic dianhydride components were added in an approximately equimolar amount to the diamine component and caused to react therewith to obtain a polyamic acid solution F with a monomer concentration of 18 mass % and a solution viscosity of 1800 poise at 25° C. The molar ratio of s-BPDA, ODPA, and PMDA was set to be 60:30:10.

Synthesis of Polyamic Acid Solution G that Forms Heat-Resistant Polyimide

A polyamic acid solution G was obtained in a manner similar to that of the synthesis of the polyamic acid solution F except that the molar ratio of s-BPDA, ODPA, and PMDA was set to be 65:30:5.

Synthesis of Polyamic Acid Solution H that Forms Thermal Fusion-Bondable Polyimide

DMAc was added into a reaction vessel equipped with an agitator and a nitrogen inlet tube, and BAPP serving as a diamine component was further added. Subsequently, s-BPDA and PMDA serving as tetracarboxylic dianhydride components were added in an approximately equimolar amount to the diamine component caused to react therewith to obtain a polyamic acid solution H with a monomer concentration of 18 mass % and a solution viscosity of 850 poise at 25° C. The molar ratio between s-BPDA and PMDA was set to be 20:80.

### Reference Example 1

The polyamic acid solution A was cast on a glass plate, in the form of a thin film, heated at 120° C. for 12 minutes using an oven, and removed from the glass plate to obtain a self-supporting film. Four sides of this self-supporting film were fixed with a pin tenter, and the self-supporting film was gradually heated from 150° C. to 450° C. (the maximum heating temperature was 450° C.) in a heating furnace to perform removal of the solvent and imidization. Thus, a polyimide film A with a thickness of 25 μm was obtained. Table 1 shows the evaluation results of the polyimide film A.

### Reference Example 2

A polyimide film B with a thickness of 25 μm was obtained in a manner similar to that of Reference Example 1 except that the polyamic acid solution B was cast on the glass plate, in the form of a thin film. Table 1 shows the evaluation results of the polyimide film B.

### Reference Example 3

A polyimide film C with a thickness of 25 μm was obtained in a manner similar to that of Reference Example I except that the polyamic acid solution C was cast on the glass plate, in the form of a thin film. Table 1 shows the evaluation results of the polyimide film C.

### Reference Example 4

A polyimide film D with a thickness of 25 μm was obtained in a manner similar to that of Reference Example 1 except that the polyamic acid solution D was cast on the glass plate, in the form of a thin film. Table 1 shows the evaluation results of the polyimide film D.

### Reference Example 5

A polyimide film E with a thickness of 25 μm was obtained in a manner similar to that of Reference Example 1 except that the polyamic acid solution E was cast on the glass plate, in the form of a thin film. Table 1 shows the evaluation results of the polyimide film E.

### Reference Example 6

A polyimide film F with a thickness of 25 μm was obtained in a manner similar to that of Reference Example 1 except that the polyamic acid solution F was cast on the glass plate, in the form of a thin film. Table 1 shows the evaluation results of the polyimide film F.

### Reference Example 7

A polyimide film G with a thickness of 25 μm was obtained in a manner similar to that of Reference Example 1 except that the polyamic acid solution G was cast on the glass plate, in the form of a thin film. Table 1 shows the evaluation results of the polyimide film G.

TABLE 1

| | | Acid dianbydride | | Dianrine | | Water absorption (%) | | | | | 5% Weight loss | |
|---|---|---|---|---|---|---|---|---|---|---|---|---|
| | Polyimide | (mol %) | | (mol %) | | | 25° C. | | | CTE | temperature (° C.) | |
| | film | s-BPDA | ODPA | PMDA | PPD | Saturation | 60% RH | ε | tanδ | (ppm/K) | N₂ | Air |
| Ref. Ex. 1 | A | 100 | 0 | 0 | 100 | 1.43 | 0.81 | 3.57 | 0.0063 | 11 | 612 | 615 |
| Ref. Ex. 2 | B | 80 | 20 | 0 | 100 | 1.10 | 0.51 | 3.56 | 0.0058 | 14 | 606 | 609 |
| Ref. Ex. 3 | C | 70 | 30 | 0 | 100 | 1.00 | 0.41 | | | 19 | 606 | 609 |
| Ref. Ex. 4 | D | 50 | 50 | 0 | 100 | 0.92 | 0.42 | 3.52 | 0.0049 | 17 | 600 | 596 |
| Ref. Ex. 5 | E | 40 | 60 | 0 | 100 | 0.94 | 0.61 | | | 22 | 602 | 602 |
| Ref. Ex. 6 | F | 60 | 30 | 10 | 100 | 1.23 | 0.64 | | | 17 | 605 | 609 |
| Ref. Ex. 7 | G | 65 | 30 | 5 | 100 | 1.22 | 0.64 | | | 19 | 607 | 612 |

### Example 1

The polyamic acid solution H and the polyamic acid solution C were extruded and cast from three-layer extrusion dies onto an upper surface of a smooth support made of metal in an arrangement of the polyamic acid solution H (thermal fusion-bondable layer), the polyamic acid solution C (core layer), and the polyamic acid solution H (thermal fusion-bondable layer) and made into the form of a thin film. The cast solutions in the form of a thin film were continuously dried with hot air at 145° C. to thereby form a self-supporting film. The self-supporting film was removed from the support, and then gradually heated from 200° C. to 390° C. (the maximum heating temperature was 390° C.) in a heating furnace to perform removal of the solvent and imidization. Thus, a thermal fusion-bondable polyimide film having a three-layer structure with a thickness of 25 μm (each of the two thermal fusion-bondable layers had a thickness of 4.0 μm and the core layer had a thickness of 17.0 μm) was obtained. Table 2 shows the evaluation results of the thermal fusion-bondable polyimide film.

Next, a sheet of copper foil (GHY5-93F-HA-V2 manufactured by JX Nippon Mining & Metals Corporation and having a thickness of 12 μm) was laid on both sides of the obtained thermal fusion-bondable polyimide film, and thermocompression-bonded thereto at a temperature of 320° C., and in the remaining heat for 5 minutes, at a pressing pressure of 3 MPa for a pressing time of 1 minute. Thus, a copper clad laminate in which the copper foil was laminated on both sides of the thermal fusion-bondable polyimide film was obtained. Table 2 shows the peel strength of this copper clad laminate.

### Example 2

A thermal fusion-bondable polyimide film having a three-layer structure and a copper clad laminate constituted by the thermal fusion-bondable polyimide film were obtained in a manner similar to that of Example 1 except that the thermal fusion-bondable polyimide film had a thickness of 50 μm (each of the two thermal fusion-bondable layers had a thickness of 5.7 μm and the core layer had a thickness of 38.6 μm). Table 2 shows the evaluation results.

### Comparative Example 1

A thermal fusion-bondable polyimide film having a three-layer structure and a copper clad laminate constituted by the thermal fusion-bondable polyimide film were obtained in a manner similar to that of Example 1 except that the polyamic acid solution H and the polyamic acid solution A were extruded and cast from the three-layer extrusion dies onto the upper surface of the smooth support made of metal in an arrangement of the polyamic acid solution H (thermal fusion-bondable layer), the polyamic acid solution A (core layer), and the polyamic acid solution H (thermal fusion-bondable layer) and made into the form of a thin film. Table 2 shows the evaluation results.

### Comparative Example 2

A thermal fusion-bondable polyimide film having a three-layer structure and a copper clad laminate constituted by the thermal fusion-bondable polyimide film were obtained in a manner similar to that of Comparative Example 1 except that the thermal fusion-bondable polyimide film had a thickness of 50 μm (each of the two thermal fusion-bondable layers had a thickness of 5.7 μm and the core layer had a thickness of 38.6 μm). Table 2 shows the evaluation results.

TABLE 2

| | Polyamic acid solution | | | | | | | | | | | | |
|---|---|---|---|---|---|---|---|---|---|---|---|---|---|
| | | Thermal | | | | | | | | | | | |
| | | fusion- | | Water absorption (%) | | | | CTE | | Peel strength | | 5% Weight loss | |
| | Core | bondable | Thickness | | 25° C. | | | (ppm/K) | | (N/mm) | | temperature (° C.) | |
| | layer | layer | (μm) | Saturation | 60% RH | ε | tanδ | MD | TD | Side A | Side B | N₂ | Air |
| Ex. 1 | C | H | 25 | 1.06 | 0.45 | 3.38 | 0.0056 | 26 | 19 | 0.9 | 1.0 | 551 | 560 |
| Ex. 2 | C | H | 50 | 1.00 | 0.62 | 3.39 | 0.0055 | 25 | 20 | 0.8 | 0.7 | 552 | 566 |
| Com. Ex. 1 | A | H | 25 | 1.39 | 0.63 | 3.39 | 0.0080 | 22 | 20 | 1.3 | 1.1 | 551 | 559 |
| Com. Ex. 2 | A | H | 50 | 1.66 | 0.98 | 3.46 | 0.0096 | 20 | 21 | 1.0 | 1.1 | 557 | 566 |

Main contents that became clear from the foregoing reference examples as well as the examples and comparative examples are as follows.

(1) The water absorption of a film decreases when both s-BPDA and ODPA are used as the tetracarboxylic acid components.
(2) In a multilayer film that has a thermal fusion-bondable layer on its surface, if the water absorption of the core layer decreases, not only the water absorption of the multilayer film decreases, but ε and tan δ also decrease.
Synthesis of Polyamic Acid Solution I that Forms Heat-Resistant Polyimide

DMAc was added into a reaction vessel equipped with an agitator and a nitrogen inlet tube, and DATP serving as a diamine component was further added. Subsequently, s-BPDA serving as a tetracarboxylic dianhydride component was added in an approximately equimolar amount to the diamine component and caused to react therewith to obtain a polyamic acid solution I with a monomer concentration of 18 mass % and a solution viscosity of 1800 poise at 25° C.

Synthesis of Polyamic Acid Solution J that Forms Heat-Resistant Polyimide

DMAc was added into a reaction vessel equipped with an agitator and a nitrogen inlet tube, and PPD and DATP serving as diamine components were further added. Subsequently, s-BPDA serving as a tetracarboxylic dianhydride component was added in an approximately equimolar amount to the diamine components and caused to react therewith to obtain a polyamic acid solution J with a monomer concentration of 18 mass % and a solution viscosity of 1800 poise at 25° C. The molar ratio between PPD and DATP was set to be 50:50.

Synthesis of Polyamic Acid Solution K that Forms Heat-Resistant Polyimide

A polyamic acid solution K was obtained in a manner similar to that of the synthesis of the polyamic acid solution J except that the molar ratio between PPD and DATP was set to be 80:20.

Synthesis of Polyamic Acid Solution L that Forms Heat-Resistant Polyimide

DMAc was added into a reaction vessel equipped with an agitator and a nitrogen inlet tube, and PPD and DATP serving as diamine components were further added. Subsequently, s-BPDA and ODPA serving as tetracarboxylic dianhydride components were added in an approximately equimolar amount to the diamine components and caused to react therewith to obtain a polyamic acid solution L with a monomer concentration of 18 mass % and a solution viscosity of 1800 poise at 25° C. The molar ratio between PPD and DATP was set to be 80:20. The molar ratio between s-BPDA and ODPA was set to be 80:20.

Synthesis of Polyamic Acid Solution M that Forms Heat-Resistant Polyimide

A polyamic acid solution M was obtained in a manner similar to that of the synthesis of the polyamic acid solution L except that the molar ratio between PPD and DATP was set to be 50:50.

Synthesis of Polyamic Acid Solution N that Forms Heat-Resistant Polyimide

DMAc was added into a reaction vessel equipped with an agitator and a nitrogen inlet tube, and DATP serving as a diamine component was further added. Subsequently, s-BPDA and ODPA serving as tetracarboxylic dianhydride components were added in an approximately equimolar amount to the diamine component and caused to react therewith to obtain a polyamic acid solution N with a monomer concentration of 18 mass % and a solution viscosity of 1800 poise at 25° C. The molar ratio between s-BPDA and ODPA was set to be 70:30.

### Reference Example 8

A polyimide film I with a thickness of 25 μm was obtained in a manner similar to that of Reference Example 1 except that the polyamic acid solution I was cast on the glass plate, in the form of a thin film. Table 3 shows the evaluation results of the polyimide film I.

### Reference Example 9

A polyimide film J with a thickness of 25 μm was obtained in a manner similar to that of Reference Example 1 except that the polyamic acid solution J was cast on the glass plate, in the form of a thin film. Table 3 shows the evaluation results of the polyimide film J.

### Reference Example 10

A polyimide film K with a thickness of 25 μm was obtained in a manner similar to that of Reference Example 1 except that the polyamic acid solution K was cast on the glass plate, in the form of a thin film. Table 3 shows the evaluation results of the polyimide film K.

### Reference Example 11

A polyimide film L with a thickness of 25 μm was obtained in a manner similar to that of Reference Example 1 except that the polyamic acid solution L was cast on the glass plate, in the form of a thin film. Table 3 shows the evaluation results of the polyimide film L.

### Reference Example 12

A polyimide film M with a thickness of 25 μm was obtained in a manner similar to that of Reference Example 1 except that the polyamic acid solution M was cast on the glass plate, in the form of a thin film. Table 3 shows the evaluation results of the polyimide film M.

### Reference Example 13

A polyimide film N with a thickness of 25 μm was obtained in a manner similar to that of Reference Example 1 except that the polyamic acid solution N was cast on the glass plate, in the form of a thin film. Table 3 shows the evaluation results of the polyimide film N.

TABLE 3

| | | Acid dianbydride | | Dianrine | | Water absorption (%) | | | | | 5% Weight loss | |
|---|---|---|---|---|---|---|---|---|---|---|---|---|
| | Polyimide | (mol %) | | (mol %) | | | 25° C. | | | CTE | temperature (° C.) | |
| | film | s-BPDA | ODPA | PPD | DATP | Saturation | 60% RH | ε | tanδ | (ppm/K) | N₂ | Air |
| Ref. Ex. 8 | I. | 100 | 0 | 0 | 100 | 0.65 | 0.26 | 3.55 | 0.0037 | 8 | 615 | 609 |
| Ref. Ex. 9 | J | 100 | 0 | 50 | 50 | | | | | 12 | 617 | 620 |
| Ref. Ex. 10 | K | 100 | 0 | 80 | 20 | 1.02 | 0.49 | 3.51 | 0.0050 | 10 | 616 | 619 |
| Ref. Ex. 11 | L | 80 | 20 | 80 | 20 | 1.02 | 0.31 | 3.54 | 0.0041 | 10 | 607 | 611 |
| Ref. Ex. 12 | M | 80 | 20 | 50 | 50 | 0.56 | 0.44 | 3.51 | 0.0035 | 16 | 612 | 616 |
| Ref. Ex. 13 | N | 70 | 30 | 0 | 100 | 0.56 | 0.40 | | | 12 | 611 | 616 |

### Example 3

The polyamic acid solution H and the polyamic acid solution K were extruded and cast from three-layer extrusion dies onto an upper surface of a smooth support made of metal in an arrangement of the polyamic acid solution H (thermal fusion-bondable layer), the polyamic acid solution K (core layer), and the polyamic acid solution H (thermal fusion-bondable layer) and made into the form of a thin film. The cast solutions in the form of a thin film were continuously dried with hot air at 145° C. to thereby form a self-supporting film. The self-supporting film was removed from the support, and then gradually heated from 200° C. to 390° C. (the maximum heating temperature was 390° C.) in a heating furnace to perform removal of the solvent and imidization. Thus, a thermal fusion-bondable polyimide film having a three-layer structure with a thickness of 50 μm (each of the two thermal fusion-bondable layers had a thickness of 5.7 μm and the core layer had a thickness of 38.6 μm) was obtained. Table 4 shows the evaluation results of the thermal fusion-bondable polyimide film.

### Example 4

The polyamic acid solution H and the polyamic acid solution L were extruded and cast from three-layer extrusion dies onto an upper surface of a smooth support made of metal in an arrangement of the polyamic acid solution H (thermal fusion-bondable layer), the polyamic acid solution L (core layer), and the polyamic acid solution H (thermal fusion-bondable layer) and made into the form of a thin film. The cast solutions in the form of a thin film were continuously dried with hot air at 145° C. to thereby form a self-supporting film. The self-supporting film was removed from the support, and gradually heated from 200° C. to 390° C. (the maximum heating temperature was 390° C.) in a heating furnace to perform removal of the solvent and imidization. Thus, a thermal fusion-bondable polyimide film having a three-layer structure with a thickness of 25 μm (each of the two thermal fusion-bondable layers had a thickness of 4.0 μm and the thickness of the core layer was 17.0 μm) was obtained. Table 4 shows the evaluation results of the thermal fusion-bondable polyimide film.

### Example 5

A thermal fusion-bondable polyimide film having a three-layer structure was obtained in a manner similar to that of Example 4 except that the thermal fusion-bondable polyimide film had a thickness of 50 μm (each of the two thermal fusion-bondable layers had a thickness of 5.7 μm and the core layer had a thickness of 38.6 μm). Table 4 shows the evaluation results.

TABLE 4

| | Polyamic acid solution | | | | | | | | | | |
|---|---|---|---|---|---|---|---|---|---|---|---|
| | | Thermal | | | | | | | | | |
| | | fusion- | | Water absorption (%) | | | | CTE | | 5% Weight loss | |
| | Core | bondable | Thickness | | 25° C. | | | (ppm/K) | | temperature (° C.) | |
| | layer | layer | (μm) | Saturation | 60% RH | ε | tanδ | MD | TD | N₂ | Air |
| Ex. 3 | K | H | 50 | 0.87 | 0.48 | 3.40 | 0.0053 | 18 | 15 | 557 | 567 |
| Ex. 4 | L | H | 25 | 0.75 | 0.40 | 3.26 | 0.0046 | 26 | 18 | 551 | 562 |
| Ex. 5 | L | H | 50 | 0.74 | 0.34 | 3.40 | 0.0044 | 22 | 15 | 555 | 569 |

Main contents that became clear from the foregoing reference examples as well as the examples and comparative examples are as follows.

(1) Even when both of s-BPDA and ODPA are used as the tetracarboxylic acid components, and, furthermore, both of PPD and DATP are used as the diamine components, the 5% weight loss temperature does not decrease, while the water absorption and tan δ decrease.

### INDUSTRIAL APPLICABILITY

The polyimide film for metal lamination of the present invention is a polyimide film for metal lamination that has a reduced dielectric constant and dielectric loss tangent while maintaining high heat resistance, and is useful as an electronic circuit board material, in particular, a circuit board material for high-frequency uses.

1. A polyimide film for metal lamination comprising a heat-resistant polyimide layer and a metal adhesion layer which is provided on at least one side of the heat-resistant polyimide layer,
a 5% weight loss temperature in a nitrogen atmosphere being 500° C. or greater, and
a dielectric loss tangent at a frequency of 11.4 GHz being 0.007 or less.

2. The polyimide film for metal lamination according to claim 1,
wherein a polyimide that composes the heat-resistant polyimide layer is a polyimide including a repeating unit represented by a chemical formula (1) below: 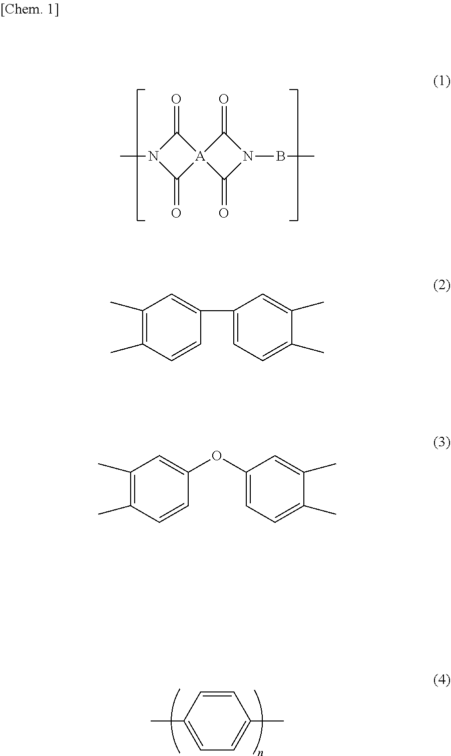
wherein, in the formula (1),
A represents a group represented by a chemical formula (2) above in an amount of 50 to 100 mol % and a group represented by a chemical formula (3) above in an amount of 0 to 50 mol %,
B represents a group represented by a chemical formula (4) above in an amount of 50 to 100 mol % and may optionally include two or more types of groups, and, in the formula (4), “n” represents an integer of 1 to 4.

3. The polyimide film for metal lamination according to claim 1,
wherein the metal adhesion layer comprises a thermal fusion-bondable polyimide.

4. The polyimide film for metal lamination according to claim 1,
wherein the metal adhesion layer comprises a heat-resistant polyimide and a silane coupling agent.

5. A polyimide metal laminate comprising: the polyimide film for metal lamination according to claim 1; and a metal layer laminated on the side of the polyimide film on which the metal adhesion layer is arranged.

6. The polyimide film for metal lamination according to claim 2, wherein the metal adhesion layer comprises a thermal fusion-bondable polyimide.

7. The polyimide film for metal lamination according to claim 2, wherein the metal adhesion layer comprises a heat-resistant polyimide and a silane coupling agent.

8. A polyimide metal laminate comprising:
the polyimide film for metal lamination according to claim 2; and
a metal layer laminated on the side of the polyimide film on which the metal adhesion layer is arranged.

9. A polyimide metal laminate comprising:
the polyimide film for metal lamination according to claim 3; and
a metal layer laminated on the side of the polyimide film on which the metal adhesion layer is arranged.

10. A polyimide metal laminate comprising:
the polyimide film for metal lamination according to claim 4; and
a metal layer laminated on the side of the polyimide film on which the metal adhesion layer is arranged.

11. A polyimide metal laminate comprising:
the polyimide film for metal lamination according to claim 6; and
a metal layer laminated on the side of the polyimide film on which the metal adhesion layer is arranged.

12. A polyimide metal laminate comprising:
the polyimide film for metal lamination according to claim 7; and
a metal layer laminated on the side of the polyimide film on which the metal adhesion layer is arranged.
